(19) United States
(12) Patent Application Publication
(10) Pub. No.: US 2025/0372170 A1
(43) Pub. Date: Dec. 4, 2025

(54) MEMORY, OPERATION METHOD OF MEMORY, AND MEMORY SYSTEM

(71) Applicant: YANGTZE MEMORY TECHNOLOGIES CO., LTD., Wuhan (CN)

(72) Inventor: Dongfang LI, Wuhan (CN)

(21) Appl. No.: 18/816,889

(22) Filed: Aug. 27, 2024

(30) Foreign Application Priority Data
May 31, 2024 (CN) 2024107060168

(51) Int. Cl. G11C 16/06; G11C 16/04

(52) U.S. Cl. CPC G11C 16/06; G11C 16/0483

(57) ABSTRACT

The application provides a memory includes a memory array and a peripheral circuit coupled to the memory array, wherein the peripheral circuit includes a control logic circuit and a page buffer. The page buffer includes a first page buffer and a second page buffer, the control logic circuit is coupled to the first page buffer through a first stagger control line, and is coupled to the second page buffer through a second stagger control line. The control logic circuit is configured to: apply an operation voltage to the page buffer through a signal line; and during the application of the operation voltage to the page buffer, apply a control voltage to the first page buffer through the first stagger control line in a first stage, and apply a control voltage to the second page buffer through the second stagger control line in a second stage.

### CROSS-REFERENCE TO RELATED APPLICATIONS

The present application claims priority to Chinese Patent Application No. 2024107060168, which was filed May 31, 2024, is titled “A MEMORY, MEMORY OPERATING METHOD AND MEMORY SYSTEM,” and is hereby incorporated herein by reference in its entirety.

### TECHNICAL FIELD

The present application relates to the technical field of semiconductor chips, and particularly to a memory, an operation method of a memory, and a memory system.

### BACKGROUND

A flash memory is a memory having characteristics of non-volatile data storage, fast read-write speed, low power consumption, and long service life, and thus is widely applied to various electronic products such as mobile phones, computers, smart sensors, positioning devices, etc. With the iteration of processes, the size of a transistor continues to reduce. In order to ensure that the memory can correctly realize data read and write operations, layout design of routings in the memory becomes more precise and complex.

### SUMMARY

In a first aspect, the present application provides a memory. The memory comprises a memory array and a peripheral circuit coupled to the memory array, wherein the peripheral circuit comprises a control logic circuit and a page buffer. The page buffer is coupled with the memory array through a bit line. The control logic circuit is coupled with the page buffer through a signal line, the page buffer includes a first page buffer and a second page buffer, and the control logic circuit is coupled with the first page buffer through a first stagger control line, and is coupled with the second page buffer through a second stagger control line. The control logic circuit is configured to: apply an operation voltage to the page buffer through the signal line; and during the application of the operation voltage to the page buffer, apply a control voltage to the first page buffer through the first stagger control line in a first stage, and apply the control voltage to the second page buffer through the second stagger control line in a second stage, so as to control the first page buffer and the second page buffer to work in a stagger manner.

In some possible implementations, the first stage is continuous with the second stage.

In some possible implementations, a duration of the first stage is equal to a duration of the second stage.

In some possible implementations, the page buffer comprises a sensing node, a first latch, a second latch, and a stagger transistor. The first latch and the second latch are coupled with a same pull-down transistor through the stagger transistor. A control end of the pull-down transistor is coupled with the sensing node, and the sensing node is coupled with the bit line.

In some possible implementations, a control end of the stagger transistor in the first page buffer is coupled with the first stagger control line, and a control end of the stagger transistor in the second page buffer is coupled with the second stagger control line. The control logic circuit is configured to: during the application of the operation voltage to the first latch or the second latch in the page buffer through the signal line, apply the control voltage to the control end of the stagger transistor in the first page buffer through the first stagger control line, so as to control the stagger transistor in the first page buffer to be turned on; or apply the control voltage to the control end of the stagger transistor in the second page buffer through the second stagger control line, so as to control the stagger transistor in the second page buffer to be turned on.

In some possible implementations, the first latch and the second latch are latch circuits, and the latch circuit comprises a first inverter, a second inverter, a setting transistor, and a resetting transistor. An input end of the first inverter is coupled with an output end of the second inverter, and an input end of the second inverter is coupled with an output end of the first inverter. A first end of the setting transistor is coupled with the input end of the first inverter, a first end of the resetting transistor is coupled with the input end of the second inverter, a second end of the setting transistor and a second end of the resetting transistor are coupled with a first end of the stagger transistor, a second end of the stagger transistor is coupled with a first end of the pull-down transistor, and a second end of the pull-down transistor is grounded.

In some possible implementations, the signal line comprises a first setting signal line, a second setting signal line, a first resetting signal line, and a second resetting signal line. The first setting signal line is coupled with a control end of the setting transistor in the first latch, the first resetting signal line is coupled with a control end of the resetting transistor in the first latch, the second setting signal line is coupled with a control end of the setting transistor in the second latch, and the second resetting signal line is coupled with a control end of the resetting transistor in the second latch.

In some possible implementations, the control logic circuit is configured to: apply a first setting voltage to the control end of the setting transistor in the first latch through the first setting signal line, apply a first resetting voltage to the control end of the resetting transistor in the first latch through the first resetting signal line, apply a second setting voltage to the control end of the setting transistor in the second latch through the second setting signal line, and apply a second resetting voltage to the control end of the resetting transistor in the second latch through the second resetting signal line.

In some possible implementations, a width of the signal line is not less than 0.85 microns.

In some possible implementations, the signal line is disposed at a metal M5 layer or a top metal TM layer.

In a second aspect, the present application provides an operation method of a memory. The memory comprises a memory array and a peripheral circuit coupled to the memory array, wherein the peripheral circuit comprises a page buffer coupled with the memory array through a bit line. The operation method comprises: applying an operation voltage to the page buffer, wherein the page buffer comprises a first page buffer and a second page buffer; and during the application of the operation voltage to the page buffer, applying a control voltage to the first page buffer in a first stage, and applying the control voltage to the second page buffer in a second stage, so as to control the first page buffer and the second page buffer to work in a stagger manner.

In some possible implementations, the first stage is continuous with the second stage.

In some possible implementations, a duration of the first stage is equal to a duration of the second stage.

In some possible implementations, the page buffer comprises a sensing node, a first latch, a second latch, and a stagger transistor. The operation method comprises: applying the operation voltage to the first latch or the second latch in the page buffer, wherein the first latch and the second latch are coupled with a same pull-down transistor through the stagger transistor, and a control end of the pull-down transistor is coupled with the sensing node; and during the application of the operation voltage to the first latch or the second latch, applying the control voltage to a control end of the stagger transistor in the first page buffer, so as to control the stagger transistor in the first page buffer to be turned on; or applying the control voltage to a control end of the stagger transistor in the second page buffer, so as to control the stagger transistor in the second page buffer to be turned on.

In some possible implementations, applying the operation voltage to the first latch in the page buffer comprises: applying a first setting voltage to a control end of a setting transistor in the first latch; or applying a first resetting voltage to a control end of a resetting transistor in the first latch.

In some possible implementations, applying the operation voltage to the second latch in the page buffer comprises: applying a second setting voltage to a control end of a setting transistor in the second latch; or applying a second resetting voltage to a control end of a resetting transistor in the second latch.

In a third aspect, the present application provides a memory. The memory comprises a memory array and a peripheral circuit coupled to the memory array, wherein the peripheral circuit comprises a control logic circuit and a page buffer. The peripheral circuit comprises a control logic circuit and a page buffer, wherein the page buffer is coupled with the memory array through a bit line, and the page buffer comprises a sensing node, a first latch, a second latch, and a stagger transistor; the first latch and the second latch are coupled with a same pull-down transistor through the stagger transistor; and a control end of the pull-down transistor is coupled with the sensing node, the sensing node is coupled with the bit line, and a control end of the stagger transistor is coupled with the control logic circuit.

In some possible implementations, the first latch and the second latch are latch circuits, and the latch circuit comprises a first inverter, a second inverter, a setting transistor, and a resetting transistor. An input end of the first inverter is coupled with an output end of the second inverter, and an input end of the second inverter is coupled with an output end of the first inverter. A first end of the setting transistor is coupled with the input end of the first inverter, a first end of the resetting transistor is coupled with the input end of the second inverter, a second end of the setting transistor and a second end of the resetting transistor are coupled with a first end of the stagger transistor, a second end of the stagger transistor is coupled with a first end of the pull-down transistor, and a second end of the pull-down transistor is grounded.

In some possible implementations, both a control end of the setting transistor and a control end of the resetting transistor are coupled with the control logic circuit.

In a fourth aspect, the present application provides a memory system. The memory system comprises a memory controller and the memory of any one of the first aspect or the third aspect mentioned above, wherein the memory controller is configured to control the memory.

### BRIEF DESCRIPTION OF THE DRAWINGS

In order to illustrate the technical solutions in the present application more clearly, the drawings to be used in some examples of the present application will be briefly introduced below. Apparently, the drawings in the following description are only drawings of some examples of the present application. Those of ordinary skills in the art may also obtain other drawings according to these drawings. In addition, the drawings in the following description may be regarded as schematic diagrams, instead of limitations to an actual size of a product, an actual flow of a method, an actual timing of a signal, etc. involved in the examples of the present application.

FIG. 1 is a schematic structural diagram of a memory provided by examples of the present application;

FIG. 2 is a schematic structural diagram of a memory array provided by examples of the present application;

FIG. 3 is a local schematic cross-sectional view of a memory string provided by examples of the present application;

FIG. 4 is a schematic structural diagram of a memory and a peripheral circuit provided by examples of the present application;

FIG. 5 is a schematic diagram of a circuit structure of a page buffer provided by examples of the present application;

FIG. 6 is a schematic diagram of a circuit structure of a latch circuit provided by examples of the present application;

FIG. 7 is a schematic waveform diagram of a control voltage for a stagger control of a page buffer provided by examples of the present application;

FIG. 8 is a schematic layout diagram of signal lines in one grouping case of page buffers provided by examples of the present application;

FIG. 9 is a schematic layout diagram of signal lines in another grouping case of page buffers provided by examples of the present application;

FIG. 10 is a schematic diagram of another circuit structure of a page buffer provided by examples of the present application;

FIG. 11 is a schematic layout diagram of signal lines and stagger control lines in one grouping case of page buffers provided by examples of the present application;

FIG. 12 is a schematic layout diagram of signal lines and stagger control lines in another grouping case of page buffers provided by examples of the present application;

FIG. 13 is a flow chart of an operation method of a memory provided by examples of the present application;

FIG. 14 is a schematic waveform diagram of a control voltage for another stagger control of a page buffer provided by examples of the present application; and

FIG. 15 is a schematic structural diagram of a memory system provided by examples of the present application.

Reference signs: 100, memory; 110, memory array; 120, peripheral circuit; 121, control logic circuit; 122, I/O interface; 123. voltage generator; 124, column decoder; 125, row decoder; 126, page buffer; 127, data bus; 128, register; 200, block; 210, string; 211, top select gate; 212, memory cell; 213, bottom select gate; 310, substrate; 320, memory stack; 321, gate conductive layer; 322, dielectric layer; 410, bit line; 420, source line; 430, string select line; 440, word line; 450, ground select line; 510, charge and discharge circuit; 511, charge circuit; 512, discharge circuit; 520, sense latch; 530, low voltage threshold latch; 540, data latch; 541, first data latch; 542, second data latch; 550, cache latch; 560, stagger transistor; 570, pull-down transistor; 610, first inverter; 620, second inverter; 630, setting transistor; 640, resetting transistor; 700, memory system; and 800, memory controller.

### DETAILED DESCRIPTION

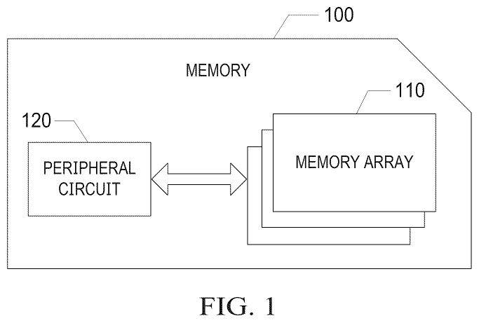

The technical solutions in some examples of the present application will be described below in conjunction with FIG. 1-FIG. 15. Apparently, the examples described are only part of, but not all of, the examples of the present application. All other examples obtained by those of ordinary skill in the art based on the examples provided by the present application shall fall in the scope of protection of the present application.

Unless otherwise specified in the context, throughout the specification and the claims, the term “comprise” is interpreted as an open and inclusive meaning, e.g., “including, but not limited to”. In the description of the specification, the terms “one example”, “some examples”, “an example”, or “in an example”, etc. are intended to indicate that particular features, structures, materials, or characteristics related to the example are included in at least one example of the present application. The schematic representation of the above terms may not necessarily refer to the same example. Furthermore, these particular features, structures, materials, or characteristics may be included in one or more examples in any suitable manner.

In the following, the terms “first” and “second” are only for the purpose of description, and cannot be construed as indicating or implying relative importance or implicitly indicating the number of indicated technical features. Thus, features defined by “first” and “second” may explicitly or implicitly include one or more of such features. In the description of the examples of the present application, “a plurality of” means two or more, unless otherwise stated.

In describing some examples, expressions of “coupled” and derivatives thereof may be used. For example, the term “coupled” may be used in the description of some examples to indicate that two or more components have a direct physical contact or an electrical contact. In this case, “coupled” may be also described as “connected”. Moreover, the term “coupled” may also mean that two or more components have no direct contact with each other, but still collaborate or interact with each other. The examples disclosed here are not necessarily limited to the content herein.

The use of “configured to” herein means open and inclusive language, and does not exclude a device suitable for performing or configured to perform additional tasks or operations.

FIG. 1 shows a schematic structural diagram of a memory provided by implementations of the present application. As shown in FIG. 1, the memory 100 may comprise a memory array 110 and a peripheral circuit 120, wherein the peripheral circuit 120 is coupled with the memory array 110. In some implementations, the peripheral circuit 120 and the memory array 110 may be respectively independently manufactured on two wafers by employing different semiconductor manufacturing processes. Then the two wafers are bonded so that the peripheral circuit 120 and the memory array 110 are bonded. In some examples, the memory array 110 may ensure the stability of storage data by employing a mature manufacturing process (for example, any manufacturing process of 22 nm, 28 nm and above, etc.). The peripheral circuit 120 may be manufactured by employing an advanced manufacturing process (for example, any manufacturing process of 14 nm, 10 nm and below, etc.), so as to facilitate improving a data reading/writing speed of the memory 100.

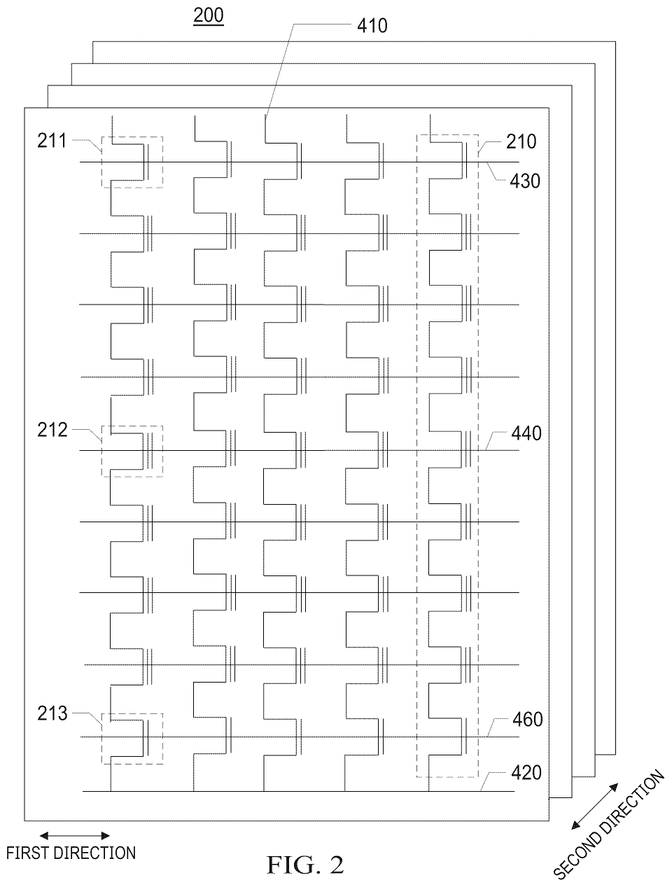

As shown in FIG. 2, in some implementations, the memory array 110 may comprise a plurality of blocks 200. The block 200 may comprise a plurality of strings 210, wherein each string 210 may comprise a top select gate (TSG) 211, a plurality of memory cells 212, and a bottom select gate (BSG) 213, which are sequentially connected in series and stacked. In the examples of the present application, the memory cells 212 may be devices capable of storing charge such as floating gate transistors or charge trap field effect transistors, etc.

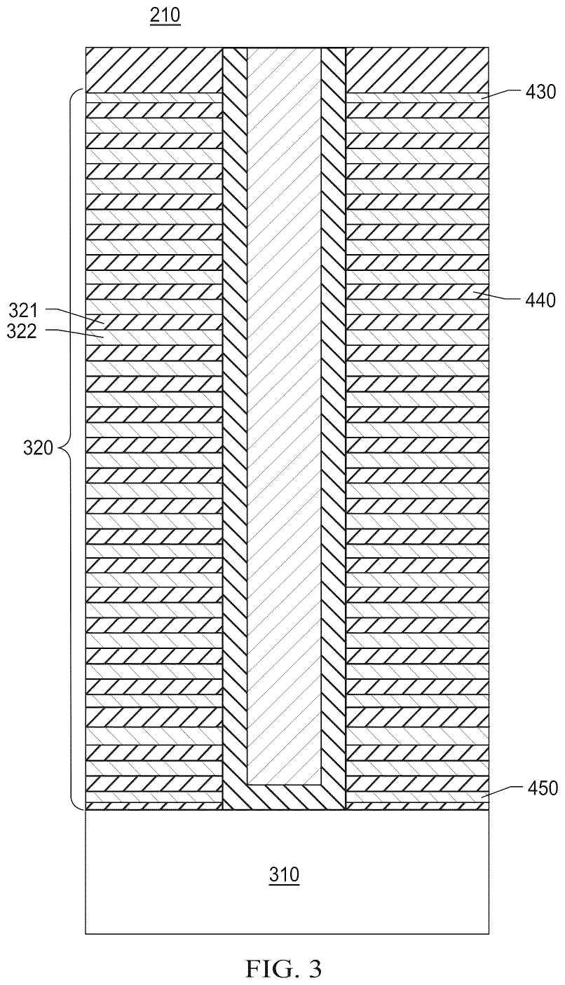

FIG. 3 shows a local schematic cross-sectional view of one possible string. The string 210 may extend vertically through a memory stack 320 above a substrate 310. The substrate 310 may comprise silicon (e.g., single crystalline silicon), silicon germanium (SiGe), gallium arsenide (GaAs), germanium (Ge), silicon on insulator (SOI), germanium on insulator (GOI), or any other suitable materials.

The memory stack 320 may comprise gate conductive layers 321 and dielectric layers 322 alternated with each other. The number of the gate conductive layers 321 and the dielectric layers 322 in the memory stack 320 is related to the number of the memory cells 212 in the string 210.

The gate conductive layer 321 may comprise a conductive material. The conductive material includes, but is not limited to, tungsten (W), cobalt (Co), copper (Cu), aluminum (Al), polysilicon, doped silicon, silicide, or any combination thereof. In some implementations, each gate conductive layer 321 comprises a metal layer, e.g., a tungsten layer. In some implementations, each gate conductive layer 321 comprises a doped polysilicon layer. Each gate conductive layer 321 may comprise a control gate surrounding the memory cell 212, and the gate conductive layer 321 at the top of the memory stack 320 may horizontally extend as a string select line (SSL) 430, the gate conductive layer 321 at the bottom of the memory stack 320 may horizontally extend as a ground select line (GSL) 450, or the gate conductive layers 321 between the string select line 430 and the ground select line 450 may horizontally extend as word lines (WLs) 440.

It is to be understood that, although not shown in FIG. 3, additional components for the string 210 may be formed, and the additional components include, but are not limited to, gate line slits/source contacts, local contacts, interconnect layers, etc.

As shown in FIG. 2, the strings 210 may be arranged into one row along a first direction, and a plurality of rows of the strings 210 may be arranged as block 200 along a second direction perpendicular to the first direction. In some examples, in the strings 210 of the same row, a gate of the top select gate 211 of each string 210 may be coupled to the same string select line 430. In some examples, the gates of the top select gates 211 of part of the plurality of rows of the strings 210 may be coupled to the same string select line 430, and the strings 210 in which the gates of the top select gates 211 are coupled to the same string select line 430 may constitute a memory slice. A gate of the bottom select gate 213 of each string 210 may be coupled to the same ground select line 450. In some implementations, a selected string 210 may be activated during a read operation and a program operation through the string select line 430 and the ground select line 450.

Each string 210 is coupled with the peripheral circuit 120 through a corresponding bit line (BL) 410, for example, a drain of the top select gate 211 in the string 210 is coupled with the bit line 410. In order to reduce the number of the bit lines 410, each of the strings 210 of any row and the string 210 at a corresponding position in other rows may be coupled to the same bit line 410.

For the plurality of strings 210 in the block 200, each of control gates of the memory cells 212 in any one of the strings 210 and control gate of the memory cell 212 at a corresponding position in other strings 210 may be coupled to the same word line 440. Sources of the bottom select gates 213 of the strings 210 may be coupled to a common source line (CSL) 420.

It is to be noted that, the drawings of the present application only exemplarily show a structure of the block 200 of some examples, but in practice, the block 200 may also be constructed in other manners.

The peripheral circuit 120 is configured to control the memory array 110. In some examples, the peripheral circuit 120 may perform the program operation on the memory cells 212 in the memory array 110 to cause the memory cells 212 to store charges, so as to realize write data “0”. The peripheral circuit 120 may perform an erase operation on the memory cells 212 to remove (or neutralize) the charges that have been stored in the memory cells 212, so as to realize write data “1”. The peripheral circuit 120 may also perform the read operation on the memory cells 212 in the memory array 110 to read data stored in the memory cells 212.

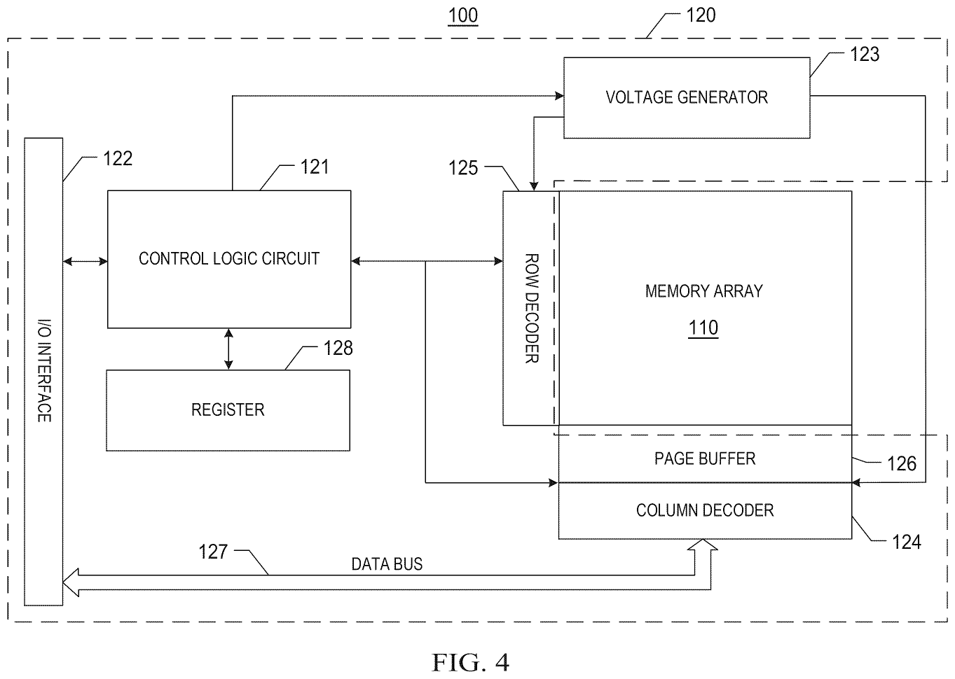

As shown in FIG. 4, in some implementations, the peripheral circuit 120 comprises a control logic circuit 121, an I/O interface 122, a voltage generator 123, a column decoder 124, a row decoder 125, a page buffer (PB) 126, a data bus 127, and a register 128. It is to be understood that, in some examples, additional circuits not shown in FIG. 4 may be comprised as well.

The control logic circuit 121 may be coupled to the voltage generator 123, the page buffer 126, the column decoder 124, the row decoder 125, the I/O interface 122, etc., and is configured to control operations of various peripheral circuits 120. The control logic circuit 121 may generate operation signals to control operations of the row decoder 125, the column decoder 124, the page buffer 126, and the voltage generator 123 in response to received commands (CMDs) or control signals, wherein the commands may be a program command, a read command, etc.

The I/O interface 122 may be coupled to the control logic circuit 121 and act as a control buffer to buffer and relay received control commands to the control logic circuit 121, and buffer and relay state information received from the control logic circuit 121 to a host. The I/O interface 122 may also be coupled to the page buffer 126 via the data bus 127 and act as a data I/O interface 122 and a data buffer to buffer and relay the data to and from the memory array 110.

The voltage generator 123 may use an external supply voltage or an internal supply voltage to generate various voltages for performing erase, program, read, verify, etc. operations on the memory array 110, for example, a program voltage, a pass voltage, a read voltage, a verify voltage, etc., and a combination thereof applied to the word line 440.

The column decoder 124 may be controlled in response to the control logic circuit 121, and select one or more strings 210 in the memory array 110 by applying a bit line 410 voltage generated from the voltage generator 123.

The row decoder 125 may be controlled in response to the control logic circuit 121, and supply a word line 440 voltage generated from the voltage generator 123 to a selected word line 440 and an unselected word line 440 of the memory array 110. As described below in detail, the row decoder 125 is configured to perform the program operation on the memory 100 cells coupled to one or more selected word lines 440 in the memory array 110.

The page buffer 126 is coupled with the memory array 110 through the bit line 410. In some examples, the page buffer 126 may read and program (write) data from and to the memory array 110 according to a control signal from the control logic circuit 121. In some other examples, the page buffer 126 may store program data (write data) to be programmed into the memory array 110. In some yet other examples, the page buffer 126 may further perform a program verify operation to ensure that the data has been properly programmed into the memory cell 212 coupled to the selected word line 440.

The register 128 may be coupled to the control logic circuit 121 and comprise a state register, a command register, and an address register for storing state information, a command operation code (OP code), and a command address for controlling the operation of each peripheral circuit 120.

It is to be understood by those skilled in the art that operations performed by the row decoder 125, the page buffer 126, the control logic circuit 121, and the voltage generator 123 described in the present application may be performed by a processing circuit. The processing circuit may include, but is not limited to, hardware of a logic circuit or a hardware/software combination of a processor performing software.

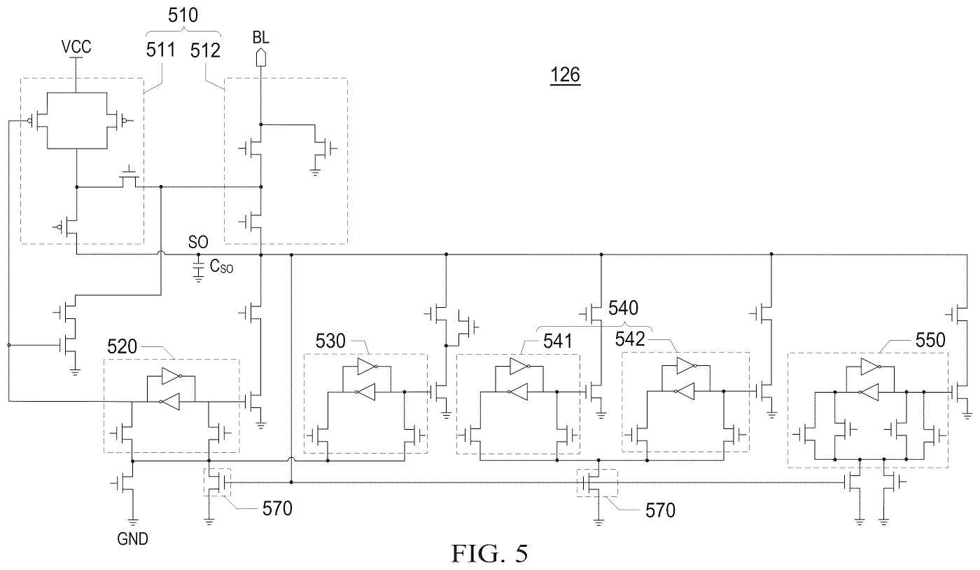

As shown in FIG. 5, the page buffer 126 comprises a sensing node (SO), a charge and discharge circuit 510, a sense latch 520, a low voltage threshold latch 530, a data latch 540, and a cache latch 550. The sensing node SO may be coupled to the memory array 110 through the bit line 410. In some implementations, a capacitor for storing charges may be disposed between the sensing node SO and the ground GND, or between the sensing node SO and any one of fixed potential nodes (which may also be referred to as reference voltage nodes). In some other implementations, a parasitic capacitor for storing charges may also be formed between the sensing node SO and the ground GND, or between the sensing node SO and any one of fixed potential nodes.

The charge and discharge circuit 510 is coupled to the sensing node SO, and the charge and discharge circuit 510 may comprise a charge circuit 511 configured to charge the sensing node SO, and a discharge circuit 512 configured to discharge the sensing node SO. A first end of the charge circuit 511 is configured to input a power supply voltage (VCC), and a second end of the charge circuit 511 is coupled to the sensing node SO, such that when the sensing node SO is charged, the sensing node SO may be charged to the power supply voltage VCC. A first end of the discharge circuit 512 is coupled to the bit line 410, and a second end of the discharge circuit 512 is coupled to the sensing node SO. It is to be understood that, the charging (or discharging) of the sensing node SO described in the present application is essentially the charging (or discharging) of the capacitor (or the parasitic capacitor) coupled with the sensing node SO.

In some implementations, various latches in the page buffer 126 may be configured to perform different operations, for example, the sense latch 520 may perform a sensing operation according to a voltage of the sensing node SO, the low voltage threshold latch 530 may perform fail bit count (FBC), the data latch 540 may perform a data transmission operation, and the cache latch 550 may perform a data input/output operation.

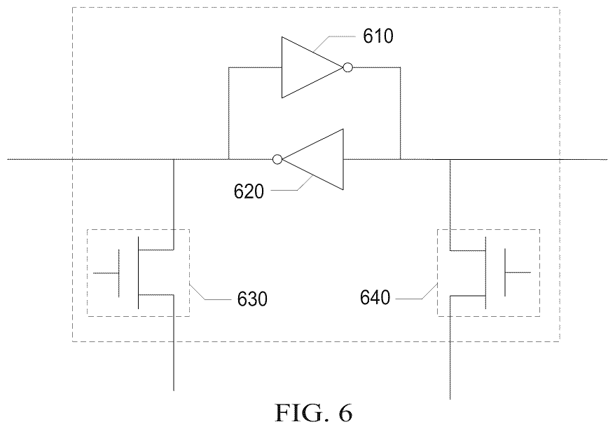

The sense latch 520, the low voltage threshold latch 530, the data latch 540, and the cache latch 550 are latch circuits. As shown in FIG. 6, the latch circuit comprises a first inverter 610, a second inverter 620, a setting transistor 630, and a resetting transistor 640. An input end of the first inverter 610 is coupled with an output end of the second inverter 620, and an input end of the second inverter 620 is coupled with an output end of the first inverter 610. Both a control end of the setting transistor 630 and a control end of the resetting transistor 640 are coupled with the control logic circuit 121. A first end of the setting transistor 630 is coupled with the input end of the first inverter 610, and a first end of the resetting transistor 640 is coupled with the input end of the second inverter 620, and a second end of the setting transistor 630 and a second end of the resetting transistor 640 are coupled with a first end of a pull-down transistor 570, a second end of the pull-down transistor 570 is coupled to the ground GND, and a control end of the pull-down transistor 570 is coupled with the sensing node SO.

Continuously referring to FIG. 5, in some implementations, the sense latch 520 and the low voltage threshold latch 530 may share one pull-down transistor 570, such that the number of the pull-down transistors 570 is reduced. For example, the second end of the setting transistor 630 and the second end of the resetting transistor 640 provided in the sense latch 520, as well as the second end of the setting transistor 630 and the second end of the resetting transistor 640 provided in the low voltage threshold latch 530, are coupled with the same pull-down transistor 570. In some implementations, the data latch 540 comprises a first data latch 541 and a second data latch 542, and the first data latch 541 and the second data latch 542 share one pull-down transistor 570.

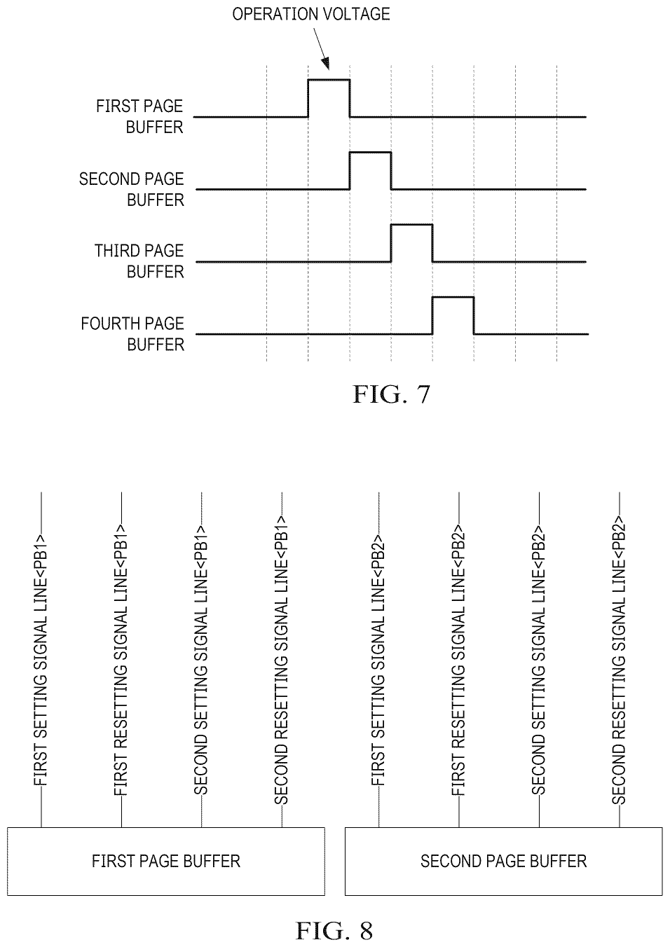

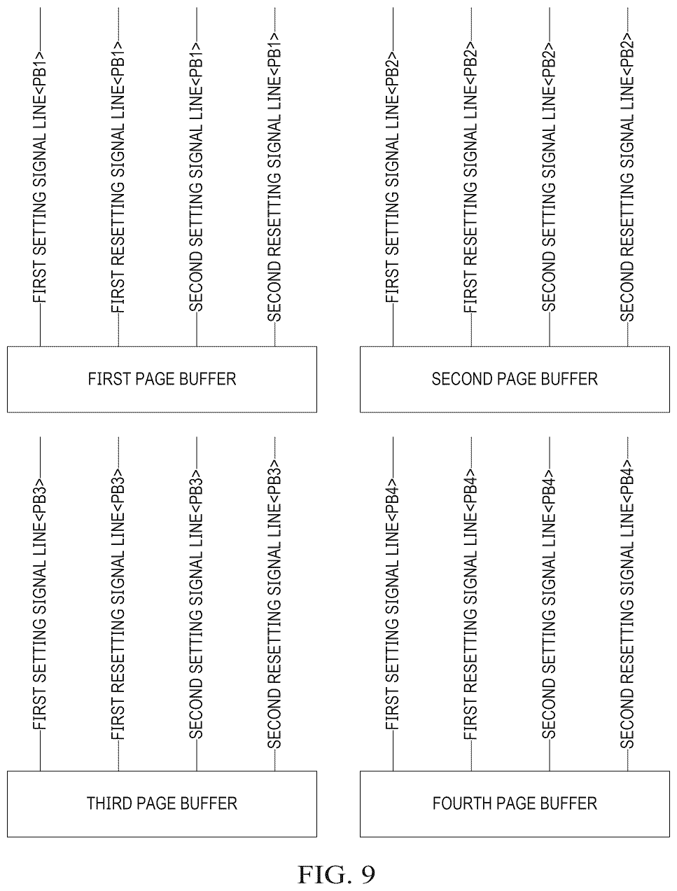

Due to the large number of the page buffers, a large peak current is caused when a great many page buffers operate at the same time. Therefore, as shown in FIG. 7, in some implementations, through stagger control, e.g., the page buffers are grouped, and operation voltages are sequentially applied to various groups of page buffers, the peak current is reduced. In some examples, the page buffers may be grouped into two groups, e.g., the page buffers are divided into first page buffers (PB1) and second page buffers (PB2). In some other examples, the page buffers may be grouped into four groups, e.g., the page buffers are divided into first page buffers (PB1), second page buffers (PB2), third page buffers (PB3), and fourth page buffers (PB4). Since each latch needs two signal lines, when the page buffers are grouped into two groups, 2×2N signal lines need to be arranged for stagger control, and when the page buffers are grouped into four groups, 4×2N signal lines need to be arranged for stagger control, wherein N is the number of the latches in the page buffers. In an example, as shown in FIG. 8, when the page buffers are grouped into two groups, 8 signal lines need to be arranged when stagger control is performed on two latches. As shown in FIG. 9, when the page buffers are grouped into four groups, 16 signal lines need to be arranged when stagger control is performed on two latches.

Thus, it can be seen that the peak current is reduced by adding the signal lines when stagger control is performed. However, with the iteration of processes, a size of the memory 100 continues to reduce, the arrangement of the signal lines also needs to be more precise and complex, thereby the difficulty of the arrangement of the signal lines is further increased.

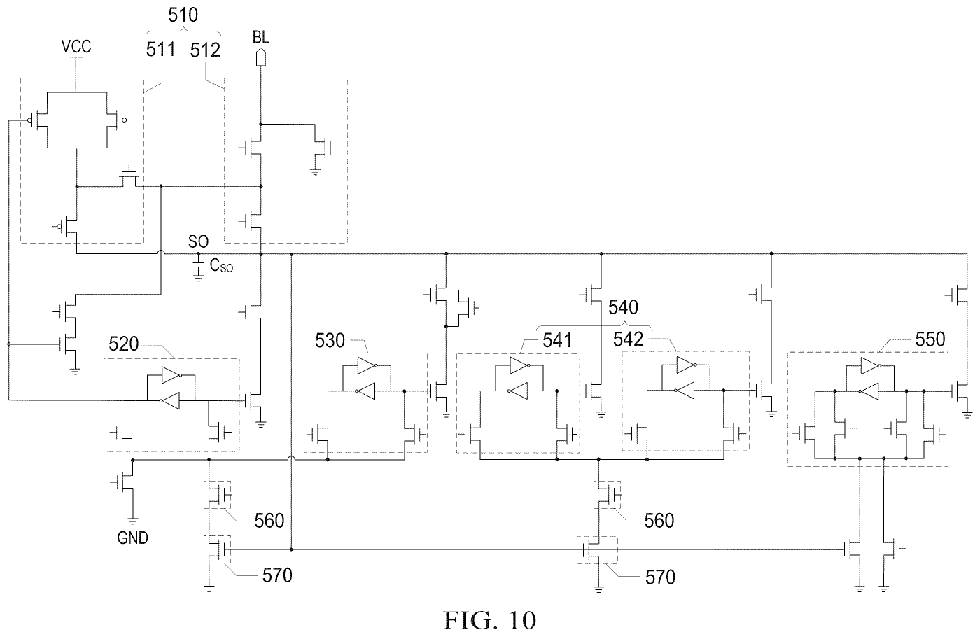

As shown in FIG. 10, in an implementation of the present application, the page buffer 126 further comprises a stagger transistor 560, a first latch (e.g., the sense latch 520 or the first data latch 541) and a second latch (e.g., the low voltage threshold latch 530 or the second data latch 542) are coupled with the same pull-down transistor 570 through the stagger transistor 560.

The control logic circuit 121 is coupled with the page buffer 126 through the signal lines, and for the first latch and the second latch sharing the pull-down transistor 570, the signal lines comprises a first setting signal line, a second setting signal line, a first resetting signal line, and a second resetting signal line. The first setting signal line is coupled with the control end of the setting transistor 630 in the first latch, and the first resetting signal line is coupled with the control end of the resetting transistor 640 in the first latch; and the second setting signal line is coupled with the control end of the setting transistor 630 in the second latch, and the second resetting signal line is coupled with the control end of the resetting transistor 640 in the second latch.

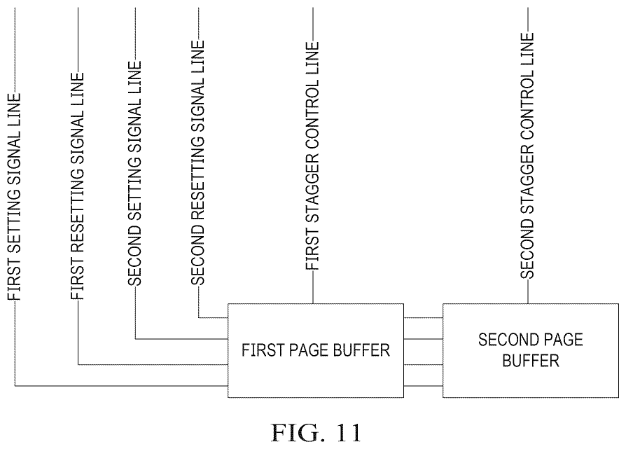

As shown in FIG. 11, in some implementations, the page buffers are grouped into two groups, the control logic circuit 121 is coupled with the first page buffer through a first stagger control line, and is coupled with the second page buffer through a second stagger control line. That is, four signal lines and two stagger control lines need to be arranged for stagger control of the first latch and the second latch, such that two (8-6) routings are saved.

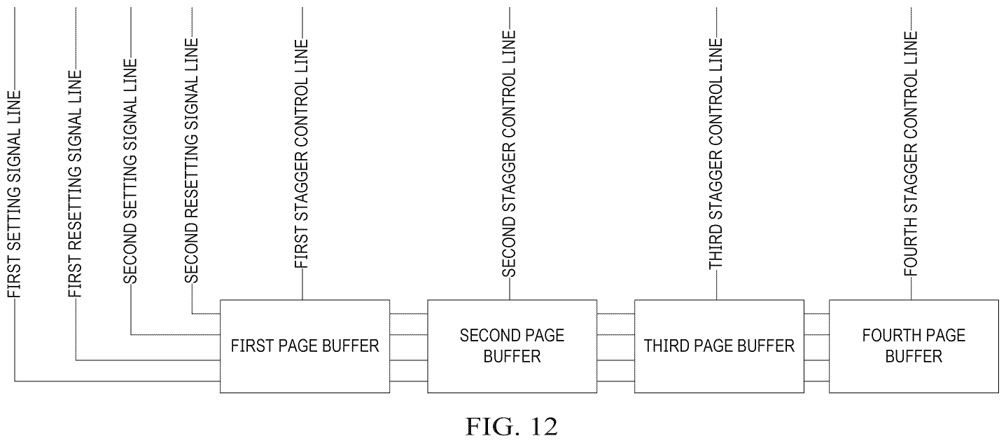

As shown in FIG. 12, in some other implementations, the page buffers are grouped into four groups, the control logic circuit 121 is coupled with the first page buffer through a first stagger control line, is coupled with the second page buffer through a second stagger control line, is coupled with the third page buffer through a third stagger control line, and is coupled with the fourth page buffer through a fourth stagger control line. That is, four stagger control lines are added. That is, four signal lines and four stagger control lines need to be arranged for stagger control of the first latch and the second latch, such that eight (16-8) routings are saved.

As shown in FIG. 10, in some examples, the sense latch 520 and the low voltage threshold latch 530 are coupled with the same pull-down transistor 570 through the stagger transistor 560, such that eight routings (the page buffers are grouped into four groups) may be saved for stagger control of the sense latch 520 and the low voltage threshold latch 530. Furthermore, the first data latch 541 and the second data latch 542 are coupled with the same pull-down transistor 570 through the stagger transistor 560, such that eight routings (the page buffers are grouped into four groups) may be saved for stagger control of the first data latch 541 and the second data latch 542. Therefore, sixteen routings may be saved for stagger control of the entire page buffers.

It is to be understood that, in some other examples, there may be more latches in the page buffer 126 sharing the same pull-down transistor 570. In an example, when the page buffers 126 are grouped into four groups, the number of the routings saved may meet the following formula: y=6x−4, wherein y is the number of the routings saved, and x is the number of the latches in the page buffer 126 sharing the same pull-down transistor 570. It can be seen that more latches in the page buffer 126 share the same pull-down transistor 570, more routings are saved.

In the implementations of the present application, the number of routings (comprising the signal lines and the stagger control lines) may be reduced, more routings are saved, an effect of reducing the difficulty of routing arrangement is more significant. Therefore, wider routings can be employed under a same area, thereby improving the overflow capacity of the routing. Alternatively, an area of the peripheral circuit 120 can be reduced, facilitating reduction in the size of the memory 100.

In some implementations, the signal lines and the stagger control lines are disposed at a top metal (TM) layer with small resistivity, or disposed at a metal layer5 (M5) layer adjacent to the top metal layer, and widths of the signal lines and the stagger control lines are not less than 0.85 microns. A spacing between the adjacent signal lines, a spacing between the adjacent stagger control lines, and a spacing between the signal line and the stagger control line adjacent to each other are not less than 0.35 microns.

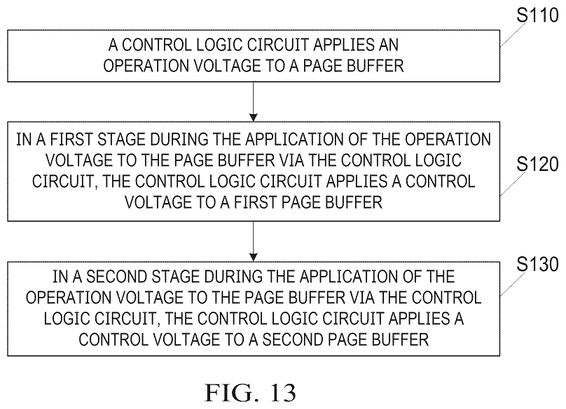

An implementation of the present application provides an operation method of a memory. As shown in FIG. 13, the operation method comprises operations S110-S130 as follows:

S110, a control logic circuit applies an operation voltage to a page buffer.

As shown in FIG. 10, the page buffer 126 comprises a first latch and a second latch, the first latch and the second latch are coupled with a same pull-down transistor 570 through a stagger transistor 560, and a control end of the pull-down transistor 570 is coupled with a sensing node SO. In some examples, the first latch may be a sense latch 520, and the second latch may be a low voltage threshold latch 530. In some other examples, the first latch may be a first data latch 541, and the second latch may be a second data latch 542.

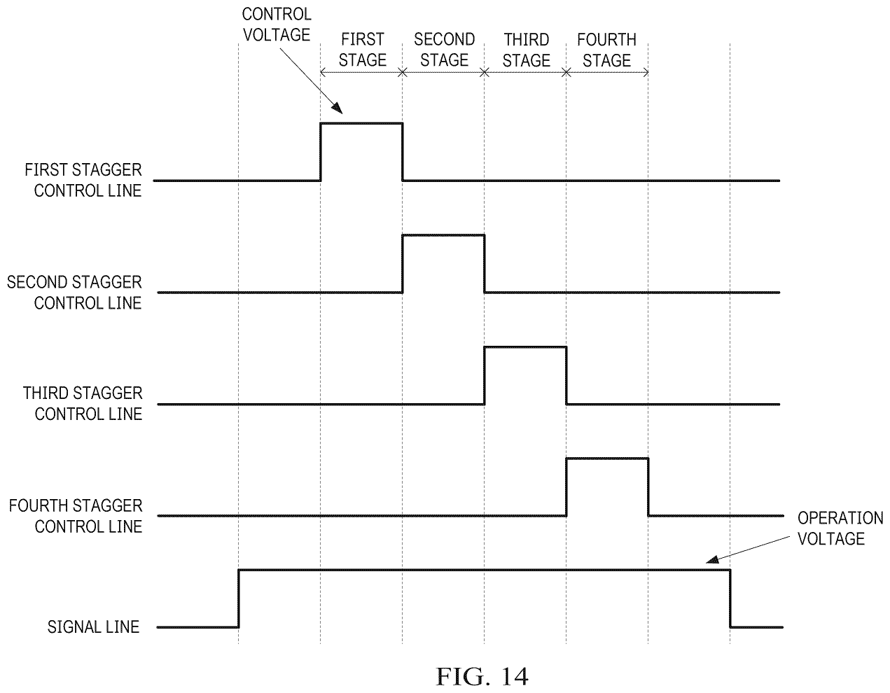

As shown in FIG. 14, in some implementations, the control logic circuit 121 may apply the operation voltage to the page buffer 126 through a signal line. In some examples, the control logic circuit 121 may apply a first setting voltage to a control end of a setting transistor 630 in the first latch through a first setting signal line. In some examples, the control logic circuit 121 may also apply a first resetting voltage to a control end of a resetting transistor 640 in the first latch through a first resetting signal line. In some examples, the control logic circuit 121 may also apply a second setting voltage to a control end of a setting transistor 630 in the second latch through a second setting signal line. In some examples, the control logic circuit 121 may apply a second resetting voltage to a control end of a resetting transistor 640 in the second latch through a second resetting signal line.

S120, in a first stage during the application of the operation voltage to the page buffer via the control logic circuit, the control logic circuit applies a control voltage to a first page buffer.

In some implementations, the page buffers comprise the first page buffer, and a control end of the stagger transistor 560 in the first page buffer is coupled with a first stagger control line. As shown in FIG. 14, in the first stage, the control logic circuit 121 applies the control voltage to the control end of the stagger transistor 560 in the first page buffer through the first stagger control line to control the stagger transistor 560 in the first page buffer to be turned on, so as to control the first page buffer to work.

S130, in a second stage during the application of the operation voltage to the page buffer via the control logic circuit, the control logic circuit applies a control voltage to a second page buffer.

In some implementations, the page buffers comprise the second page buffer, and a control end of the stagger transistor 560 in the second page buffer is coupled with a second stagger control line. As shown in FIG. 14, in the second stage, the control logic circuit 121 applies the control voltage to the control end of the stagger transistor 560 in the second page buffer through the second stagger control line to control the stagger transistor 560 in the second page buffer to be turned on, so as to control the second page buffer to work.

As shown in FIG. 14, in some implementations, the first stage is continuous with the second stage, and a duration of the first stage is equal to a duration of the second stage. By controlling the first page buffer and the second page buffer to work in a stagger manner, a peak current when the page buffer is operated is reduced.

It is to be understood that, the page buffers may also be grouped in other manners, for example, the page buffers may further comprise a third page buffer and a fourth page buffer. Therefore, the operation method may further comprise operations S140-S150.

S140, in a third stage during the application of the operation voltage to the page buffer via the control logic circuit, the control logic circuit applies a control voltage to the third page buffer.

In some implementations, a control end of the stagger transistor 560 in the third page buffer is coupled with a third stagger control line. As shown in FIG. 14, in the third stage, the control logic circuit 121 applies the control voltage to the control end of the stagger transistor 560 in the third page buffer through the third stagger control line to control the stagger transistor 560 in the third page buffer 126 to be turned on, so as to control the third page buffer 126 to work.

S150, in a fourth stage during the application of the operation voltage to the page buffer 126 via the control logic circuit 121, the control logic circuit 121 applies a control voltage to the fourth page buffer 126.

In some implementations, a control end of the stagger transistor 560 in the fourth page buffer 126 is coupled with a fourth stagger control line. As shown in FIG. 14, in the fourth stage, the control logic circuit 121 applies the control voltage to the control end of the stagger transistor 560 in the fourth page buffer through the fourth stagger control line to control the stagger transistor 560 in the fourth page buffer to be turned on, so as to control the fourth page buffer to work.

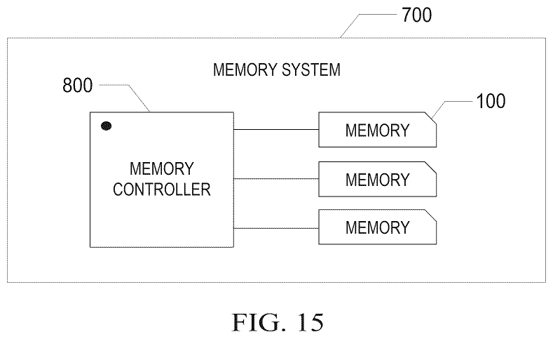

As shown in FIG. 15, an implementation of the present application provides a memory system 700. The memory system 700 comprises a memory controller 800 and a memory 100, wherein a peripheral circuit 120 of the memory 100 comprises the page buffer 126 as shown in FIG. 10. The memory controller 800 is coupled with the memory 100. In some implementations, the memory controller 800 may send various commands (e.g., a program command, a read command, an erase command, etc.) to the memory 100 based on instructions received from a host, so as to control operations (e.g., a program operation, a read operation, an erase operation, etc.) of the memory 100. When the operations of the memory 100 is controlled, the peripheral circuit 120 in the memory 100 may perform the method as shown in FIG. 13.

It is to be understood that, the memory controller 800 may further be configured to manage various functions with respect to data stored or to be stored in a memory device, including, but not limited to, bad-block management, garbage collection, logical-to-physical address translation, wear leveling, etc. Of course, the memory controller 800 may further perform any other suitable functions (for example, formatting the memory 100), which are no longer described in the present application.

In some implementations, the memory controller 800 and one or more memories 100 may be packaged into different types of electronic products. In some examples, the memory controller 800 and the single memory 100 may be integrated into a memory card. The memory card may comprise a personal computer memory card (PCMCIA card), a compact flash (CF) card, a smart media (SM) card, a memory stick, a multi-media card (MMC), a secure digital (SD) card, etc. The memory card may further comprise a memory card connector coupling the memory card with a host. In some other examples, the memory controller 800 and a plurality of memories 100 may be integrated into a solid state disk (SSD). The solid state disk may further comprise a solid state disk connector coupling the solid state disk with a host. In some implementations, at least one of a storage capacity or operation speed of the solid state disk is greater that of the memory card.

The memory controller 800 may communicate with an external device (e.g., a host) through at least one of various interface protocols. The interface protocols may comprise at least one of a universal serial bus (USB) protocol, a multi-media card (MMC) protocol, a peripheral component interconnect (PCI) protocol, a PCI-express (PCI-E) protocol, an advanced technology attachment (ATA) protocol, a serial ATA protocol, a parallel ATA protocol, a small computer system interface (SCSI) protocol, an enhanced small disk interface (ESDI) protocol, or an integrated drive electronics (IDE) protocol.

In some implementations, the memory system 700 may be applied to different types of electronic devices, such as a mobile phone (e.g., a cellphone), a desktop computer, a tablet, a notebook computer, a server, a vehicle device, a gaming console, a printer, a positioning device, a wearable device, a smart sensor, a mobile power supply, a virtual reality (VR) device, an augmented reality (AR) device, a server, etc. or any suitable electronic device that may store data.

Examples of the present application provide a memory, an operation method of a memory, and a memory system. The memory comprises a memory array and a peripheral circuit coupled to the memory array, wherein the peripheral circuit comprises a control logic circuit and a page buffer. The page buffer is coupled with the memory array through a bit line. The control logic circuit is coupled with the page buffer through a signal line, the page buffer includes a first page buffer and a second page buffer, and the control logic circuit is coupled with the first page buffer through a first stagger control line, and is coupled with the second page buffer through a second stagger control line. The control logic circuit is configured to: apply an operation voltage to the page buffer through the signal line; and during the application of the operation voltage to the page buffer, apply a control voltage to the first page buffer through the first stagger control line in a first stage, and apply a control voltage to the second page buffer through the second stagger control line in a second stage, so as to control the first page buffer and the second page buffer to work in a stagger manner. In the implementations of the present application, the number of routings is reduced, such that the arrangement difficulty of the routings is reduced. Wider routings can be employed under a same area, thereby improving the overflow capacity of the routing. Alternatively, an area of the peripheral circuit can be reduced, facilitating reduction in the size of the memory.

An example of the present application provide a computer-readable storage medium. The computer-readable storage medium stores computer-executable instructions, and after the computer-executable instructions are executed, the method as shown in FIG. 13 can be implemented.

An example of the present application provide a computer device, comprising a processor and a readable storage medium coupled with the processor, wherein the readable storage medium stores executable instructions, and when the executable instructions are executed by the processor, the method as shown in FIG. 13 can be implemented.

Those skilled in the art can clearly understand that, for ease and simplicity of description, in the above examples, the descriptions of various examples have their own emphases, and portions of some example that are not described in detail may be referred to a corresponding process in the aforementioned method examples, which is no longer repeated here.

In several examples provided by the present application, it is to be understood that the provided memory, operation method of a memory, and memory system may be implemented in other manners. For example, the division of some module is only a logical functional division. In a real implementation, there may be another manner for division. For example, a plurality of units or components may be combined, or may be integrated into another system, or some features can be ignored or not performed.

Those of ordinary skill in the art can recognize that the modules and algorithm steps of various examples described in conjunction with the examples disclosed herein can be implemented in an electronic hardware, or a combination of a computer software and an electronic hardware. Whether these functions are performed by means of a hardware or a software depends on particular applications and design constraints of the technical solution. Professional technicians can implement the described function using different methods for each particular application, but such implementation should not be considered as going beyond the scope of the present application.

The above is only the specific implementations of the present application, but the protection scope of the present application is not limited thereto. Any variations or replacements apparent to those skilled in the art within the technical scope disclosed by the present application shall fall within the protection scope of the present application. Therefore, the protection scope of the present application shall be subject to the protection scope of the claims.

What is claimed is:

1. A memory, comprising a memory array and a peripheral circuit coupled to the memory array, wherein:
the peripheral circuit comprises a control logic circuit and a page buffer;
the page buffer is coupled with the memory array through a bit line;
the control logic circuit is coupled with the page buffer through a signal line;
the page buffer comprises a first page buffer and a second page buffer;
the control logic circuit is coupled with the first page buffer through a first stagger control line and is coupled with the second page buffer through a second stagger control line; and
the control logic circuit is configured to:
apply an operation voltage to the page buffer through the signal line; and
during the application of the operation voltage to the page buffer, apply a control voltage to the first page buffer through the first stagger control line in a first stage and apply the control voltage to the second page buffer through the second stagger control line in a second stage, so as to control the first page buffer and the second page buffer to work in a stagger manner.

2. The memory of claim 1, wherein the first stage is continuous with the second stage.

3. The memory of claim 1, wherein a duration of the first stage is equal to a duration of the second stage.

4. The memory of claim 1, wherein:
the page buffer comprises a sensing node, a first latch, a second latch, and a stagger transistor;
the first latch and the second latch are coupled with a same pull-down transistor through the stagger transistor; and
a control end of the pull-down transistor is coupled with the sensing node and the sensing node is coupled with the bit line.

5. The memory of claim 4, wherein a control end of the stagger transistor in the first page buffer is coupled with the first stagger control line, a control end of the stagger transistor in the second page buffer is coupled with the second stagger control line, and the control logic circuit is configured to:
during application of the operation voltage to the first latch or the second latch in the page buffer through the signal line, apply the control voltage to the control end of the stagger transistor in the first page buffer through the first stagger control line, so as to control the stagger transistor in the first page buffer to be turned on; or
apply the control voltage to the control end of the stagger transistor in the second page buffer through the second stagger control line, so as to control the stagger transistor in the second page buffer to be turned on.

6. The memory of claim 4, wherein the first latch and the second latch are latch circuits, and the latch circuit comprises a first inverter, a second inverter, a setting transistor, and a resetting transistor, wherein:
an input end of the first inverter is coupled with an output end of the second inverter and an input end of the second inverter is coupled with an output end of the first inverter;
a first end of the setting transistor is coupled with the input end of the first inverter;
a first end of the resetting transistor is coupled with the input end of the second inverter;
a second end of the setting transistor and a second end of the resetting transistor are coupled with a first end of the stagger transistor;
a second end of the stagger transistor is coupled with a first end of the pull-down transistor; and
a second end of the pull-down transistor is grounded.

7. The memory of claim 6, wherein:
the signal line comprises a first setting signal line, a second setting signal line, a first resetting signal line, and a second resetting signal line;
the first setting signal line is coupled with a control end of the setting transistor in the first latch, and the first resetting signal line is coupled with a control end of the resetting transistor in the first latch; and
the second setting signal line is coupled with a control end of the setting transistor in the second latch, and the second resetting signal line is coupled with a control end of the resetting transistor in the second latch.

8. The memory of claim 7, wherein the control logic circuit is configured to:
apply a first setting voltage to the control end of the setting transistor in the first latch through the first setting signal line, and apply a first resetting voltage to the control end of the resetting transistor in the first latch through the first resetting signal line; and
apply a second setting voltage to the control end of the setting transistor in the second latch through the second setting signal line, and apply a second resetting voltage to the control end of the resetting transistor in the second latch through the second resetting signal line.

9. The memory of claim 1, wherein a width of the signal line is not less than 0.85 microns.

10. The memory of claim 1, wherein the signal line is disposed at a metal layer5 (M5 (layer or a top metal (TM) layer.

11. An operation method of a memory, wherein the memory comprises a memory array and a peripheral circuit coupled to the memory array, the peripheral circuit comprises a page buffer coupled with the memory array through a bit line, the operation method comprising:
applying an operation voltage to the page buffer, wherein the page buffer comprises a first page buffer and a second page buffer; and
during the application of the operation voltage to the page buffer, applying a control voltage to the first page buffer in a first stage, and applying the control voltage to the second page buffer in a second stage, so as to control the first page buffer and the second page buffer to work in a stagger manner.

12. The operation method of claim 11, wherein the first stage is continuous with the second stage.

13. The operation method of claim 11, wherein a duration of the first stage is equal to a duration of the second stage.

14. The operation method of claim 13, wherein the page buffer comprises a sensing node, a first latch, a second latch, and a stagger transistor, the operation method comprising:
applying the operation voltage to the first latch or the second latch in the page buffer, wherein the first latch and the second latch are coupled with a same pull-down transistor through the stagger transistor, and a control end of the pull-down transistor is coupled with the sensing node; and
during application of the operation voltage to the first latch or the second latch, applying the control voltage to a control end of the stagger transistor in the first page buffer, so as to control the stagger transistor in the first page buffer to be turned on; or applying the control voltage to a control end of the stagger transistor in the second page buffer, so as to control the stagger transistor in the second page buffer to be turned on.

15. The operation method of claim 14, wherein the applying the operation voltage to the first latch in the page buffer comprises:
applying a first setting voltage to a control end of a setting transistor in the first latch; or applying a first resetting voltage to a control end of a resetting transistor in the first latch.

16. The operation method of claim 14, wherein the applying the operation voltage to the second latch in the page buffer comprises:
applying a second setting voltage to a control end of a setting transistor in the second latch; or applying a second resetting voltage to a control end of a resetting transistor in the second latch.

17. A memory, comprising a memory array and a peripheral circuit coupled to the memory array, wherein:
the peripheral circuit comprises a control logic circuit and a page buffer;
the page buffer is coupled with the memory array through a bit line;
the page buffer comprises a sensing node, a first latch, a second latch, and a stagger transistor;
the first latch and the second latch are coupled with a same pull-down transistor through the stagger transistor; and
a control end of the pull-down transistor is coupled with the sensing node, the sensing node is coupled with the bit line, and a control end of the stagger transistor is coupled with the control logic circuit.

18. The memory of claim 17, wherein:
the first latch and the second latch are latch circuits;
the latch circuit comprises a first inverter, a second inverter, a setting transistor, and a resetting transistor.

19. The memory of claim 18, wherein:
an input end of the first inverter is coupled with an output end of the second inverter and an input end of the second inverter is coupled with an output end of the first inverter;
a first end of the setting transistor is coupled with the input end of the first inverter;
a first end of the resetting transistor is coupled with the input end of the second inverter;
a second end of the setting transistor and a second end of the resetting transistor are coupled with a first end of the stagger transistor;
a second end of the stagger transistor is coupled with a first end of the pull-down transistor; and
a second end of the pull-down transistor is grounded.

20. The memory of claim 18, wherein both a control end of the setting transistor and a control end of the resetting transistor are coupled with the control logic circuit.
